(19) United States
(12) Patent Application Publication
(10) Pub. No.: US 2014/0295675 A1
(43) Pub. Date: Oct. 2, 2014

(54) SILICON OXIDE FILM FORMING METHOD AND SILICON OXIDE FILM FORMING APPARATUS

(71) Applicant: Tokyo Electronic Limited, Tokyo (JP)

(72) Inventors: Toshiyuki IKEUCHI, Nirasaki City (JP); Norifumi KIMURA, Nirasaki City (JP); Tomoyuki OBU, Nirasaki City (JP)

(73) Assignee: Tokyo Electronic Limited, Tokyo (JP)

(21) Appl. No.: 14/226,020

(22) Filed: Mar. 26, 2014

(30) Foreign Application Priority Data
Mar. 27, 2013 (JP) 2013-066713
Jan. 29, 2014 (JP) 2014-014262

(51) Int. Cl. H01L 21/02

(52) U.S. Cl. CPC H01L 21/02164; H01L 21/02236
USPC 438/773; 118/704

(57) ABSTRACT

A silicon oxide film forming method includes performing a set one or more times, the set including: a standby process in which a workpiece is accommodated into and recovered from a boat; a load process in which the workpiece accommodated in the boat is loaded into a reaction chamber; a silicon oxide film formation process in which a silicon oxide film is formed on the workpiece accommodated within the reaction chamber; and an unload process in which the workpiece having the silicon oxide film is unloaded from the reaction chamber. In at least one of the unload process, the standby process and the load process, a gas containing water vapor is supplied into the reaction chamber while an interior of the reaction chamber is heated.

### CROSS-REFERENCE TO RELATED APPLICATIONS

This application claims the benefit of Japanese Patent Application Nos. 2013-066713 and 2014-014262, filed on Mar. 27, 2013 and Jan. 29, 2014, in the Japan Patent Office, the disclosure of which is incorporated herein in their entirety by reference.

### TECHNICAL FIELD

The present disclosure relates to a silicon oxide film forming method and a silicon oxide film forming apparatus.

### BACKGROUND

As a silicon oxide film forming method, there is proposed an ALD (Atomic Layer Deposition) method for forming a high-quality silicon oxide film on a workpiece, e.g., a semiconductor wafer, at a low temperature. For example, a method of forming a thin film at a low temperature between 300 degrees C. to 600 degrees C. is widely known.

A silicon oxide film as formed is deposited on (adheres to) not only the surface of a semiconductor wafer but also the internal parts of a heat treatment apparatus such as the inner wall of a reaction tube or different kinds of jigs. If deposits adhere to the internal parts of the heat treatment apparatus when forming a thin film, stresses are generated due to a difference in thermal expansion coefficient between the quartz, of which a reaction tube is made, and the deposits. In this case, the stress causes the deposits to break from the heat treatment apparatus. The broken deposits become particles, which may cause a reduction in productivity. In particular, particles are easily generated between an unload process in which a semiconductor wafer with a silicon oxide film is transferred to the outside of the reaction tube and a load process in which a new semiconductor wafer is put into the reaction tube. For that reason, there is a demand for a silicon oxide film forming method for preventing the generation of particles.

### SUMMARY

Some embodiments of the present disclosure provide a silicon oxide film forming method and a silicon oxide film forming apparatus capable of preventing generation of particles.

According to an aspect of the present disclosure, there is provided a silicon oxide film forming method including performing a set one or more times, the set including: a standby process in which a workpiece is accommodated into and recovered from a boat; a load process in which the workpiece accommodated in the boat is loaded into a reaction chamber; a silicon oxide film formation process in which a silicon oxide film is formed on the workpiece accommodated within the reaction chamber; and an unload process in which the workpiece having the silicon oxide film is unloaded from the reaction chamber, wherein, in at least one of the unload process, the standby process and the load process, a gas containing water vapor is supplied into the reaction chamber while an interior of the reaction chamber is heated.

According to another aspect of the present disclosure, there is provided a silicon oxide film forming apparatus, including: a reaction chamber configured to accommodate a workpiece mounted on a boat; a heating unit configured to heat an interior of the reaction chamber to a predetermined temperature; a film forming gas supply unit configured to supply a film forming gas into the reaction chamber; a water-vapor-containing gas supply unit configured to supply a water-vapor-containing gas into the reaction chamber; and a control unit configured to control the heating unit, the film forming gas supply unit and the water-vapor-containing gas supply unit. The control unit is configured to perform one or more time a set including: a standby process in which the workpiece is accommodated into and recovered from the boat; a load process in which the workpiece accommodate in the boat is loaded into the reaction chamber; a silicon oxide film formation process in which the film forming gas supply unit is controlled to form a silicon oxide film on the workpiece accommodated within the reaction chamber; and an unload process in which the workpiece having the silicon oxide film formed thereon is unloaded from the reaction chamber. In at least one of the load process, the standby process and the unload process, the water-vapor-containing gas supply unit is controlled to supply the water-vapor-containing gas into the reaction chamber while the heating unit is controlled to heat the interior of the reaction chamber.

### BRIEF DESCRIPTION OF THE DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a view showing a processing apparatus according to one embodiment of the present disclosure.

FIG. 2 is a view showing a configuration of a control unit employed in the processing apparatus shown in FIG. 1.

FIG. 3 is a view explaining a silicon oxide film forming method.

FIG. 4 is a view showing the film stresses of a silicon oxide film in cases of using various annealing gases.

FIG. 5 is a view showing a processing apparatus according to another embodiment of the present disclosure.

FIG. 6 is a view showing the outline of the processing apparatus in a standby process.

FIG. 7 is a view showing the relationship between the annealing gas supply time, the N₂ substitution pressure and the O₂ MAX concentration within a loading area.

FIG. 8 is a view showing the number of particles before and after supplying an annealing gas in the standby process.

### DETAILED DESCRIPTION

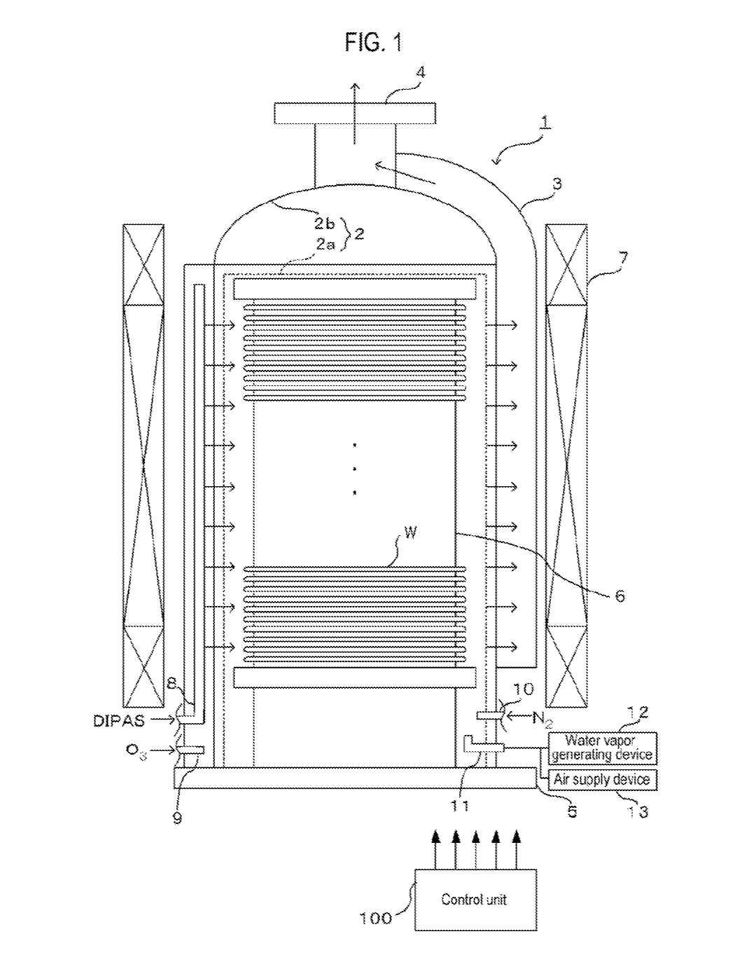

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments. A silicon oxide film forming method and a silicon oxide film forming apparatus according to some embodiments of the present disclosure will now be described in detail. In the present embodiments, the description will be made by taking as an example in which a batch-type vertical processing apparatus is used as the silicon oxide film forming apparatus of the present disclosure. FIG. 1 shows the configuration of the processing apparatus according to one embodiment.

As shown in FIG. 1, the processing apparatus 1 includes a reaction tube 2 whose longitudinal direction extends in the vertical direction. The reaction tube 2 has a double tube structure which includes an inner tube 2a and a roofed outer tube 2b configured to cover the inner tube 2a and formed in a spaced-apart relationship with the inner tube 2a. The sidewalls of the inner tube 2a and the outer tube 2b have a plurality of openings as indicated by arrows in FIG. 1. The inner tube 2a and the outer tube 2b are made of a material superior in heat resistance and corrosion resistance, e.g., quartz.

An exhaust part 3 for exhausting gas existing within the reaction tube 2 is disposed at one side of the reaction tube 2. The exhaust part 3 is formed to extend upward along the reaction tube 2 and is configured to communicate with the reaction tube 2 through the openings formed in the sidewall of the reaction tube 2. The upper end portion of the exhaust part 3 is connected to an exhaust port 4 arranged in the upper portion of the reaction tube 2. An exhaust pipe not shown is connected to the exhaust port 4. Pressure regulating mechanisms such as a valve (not shown) and a vacuum pump 127 to be described later are installed in the exhaust pipe. By virtue of the pressure regulating mechanisms, a gas supplied from one side of the sidewall of the outer tube 2b (a source gas supply pipe 8) is exhausted to the exhaust pipe through the inner tube 2a, the other side of the sidewall of the outer tube 2b, the exhaust part 3 and the exhaust port 4. Thus, the interior of the reaction tube 2 is controlled to a desired pressure (vacuum degree).

A lid 5 is disposed below the reaction tube 2. The lid 5 is made of a material superior in heat resistance and corrosion resistance, e.g., quartz. The lid 5 can be moved up and down by a boat elevator 128 to be described later. If the lid 5 is moved up by the boat elevator 128, the lower end (furnace port) of the reaction tube 2 is closed. If the lid 5 is moved down by the boat elevator 128, the lower end (furnace port) of the reaction tube 2 is opened.

A wafer boat 6 is mounted on the lid 5. The wafer boat 6 is made of, e.g., quartz. The wafer boat 6 is configured such that a plurality of semiconductor wafers W can be accommodated therein in a vertically spaced-apart relationship. Furthermore, a heat insulating container which prevents a reduction of the internal temperature of the reaction tube 2 at the furnace port of the reaction tube 2 or a rotary table may be installed on the lid 5. The wafer boat 6 for accommodating the semiconductor wafers W is rotatably mounted on the rotary table. The wafer boat 6 may be mounted on the heat insulating container or the rotary table. In this case, it becomes easy to uniformly control the temperature of the semiconductor wafers W accommodated within the wafer boat 6.

In the vicinity of the reaction tube 2, heaters 7 formed of, e.g., resistance heating elements, are installed so as to surround the reaction tube 2. The interior of the reaction tube 2 is heated to a specified temperature by the heaters 7. As a result, the semiconductor wafers W accommodated within the reaction tube 2 are heated to a specified temperature.

The source gas supply pipe 8 for supplying a source gas into the reaction tube 2 (the outer tube 2b) is inserted through the side surface near the lower end portion of the reaction tube 2. The source gas is a Si source which supplies a source material (Si) to be adsorbed to a workpiece. The source gas is used in an adsorption process to be described later. In this example, diisopropylaminosilane (DIPAS) is used as the Si source.

A plurality of supply holes is formed in the source gas supply pipe 8 by a specified interval along the vertical direction. The source gas is supplied into the reaction tube 2 (the outer tube 2b) via the supply holes. Thus, as indicated by arrows in FIG. 1, the source gas is supplied into the reaction tube 2 from a plurality of points arranged in the vertical direction.

An oxidizing gas supply pipe 9 for supplying an oxidizing gas into the reaction tube 2 (the outer tube 2b) is inserted through the side surface near the lower end portion of the reaction tube 2. The oxidizing gas is a gas which oxidizes the adsorbed source (Si). The oxidizing gas is used in an oxidation process to be described later. In this example, ozone (O₃) is used as the oxidizing gas.

A nitrogen gas supply pipe 10 for supplying nitrogen (N₂) as a diluting gas and a purge gas into the reaction tube 2 (the inner tube 2a) is inserted through the side surface near the lower end portion of the reaction tube 2.

An annealing gas supply pipe 11 for supplying an annealing gas into the reaction tube 2 (the inner tube 2a) is inserted through the side surface near the lower end portion of the reaction tube 2. The annealing gas supply pipe 11 is connected to a water vapor generating device 12 for generating a water vapor and an air supply device 13 for supplying an air. By controlling the flow rates of the water vapor and the air supplied from the water vapor generating device 12 and the air supply device 13, respectively, a gas having a desired H₂O concentration is supplied into the reaction tube 2 via the annealing gas supply pipe 11. For example, a gas having an H₂O concentration of 1% is supplied into the reaction tube 2, by controlling the flow rates of the water vapor and the air supplied from the water vapor generating device 12 and the air supply device 13, respectively, such that the flow rate ratio of the water vapor (an H₂O gas) to the air (an O₂ gas and an N₂ gas) becomes 0.2 slm:20.0 slm (equivalent to 4.0 slm of an O₂ gas and 16.0 slm of an N₂ gas).

The source gas supply pipe 8, the oxidizing gas supply pipe 9, the nitrogen gas supply pipe 10 and the annealing gas supply pipe 11 are connected to source gas supply sources (not shown) through MFCs (Mass Flow Controllers) 125 to be described later.

A plurality of temperature sensors 122, e.g., thermocouples, for measuring the internal temperature of the reaction tube 2 and a plurality of pressure gauges 123 for measuring the internal pressure of the reaction tube 2 are disposed within the reaction tube 2.

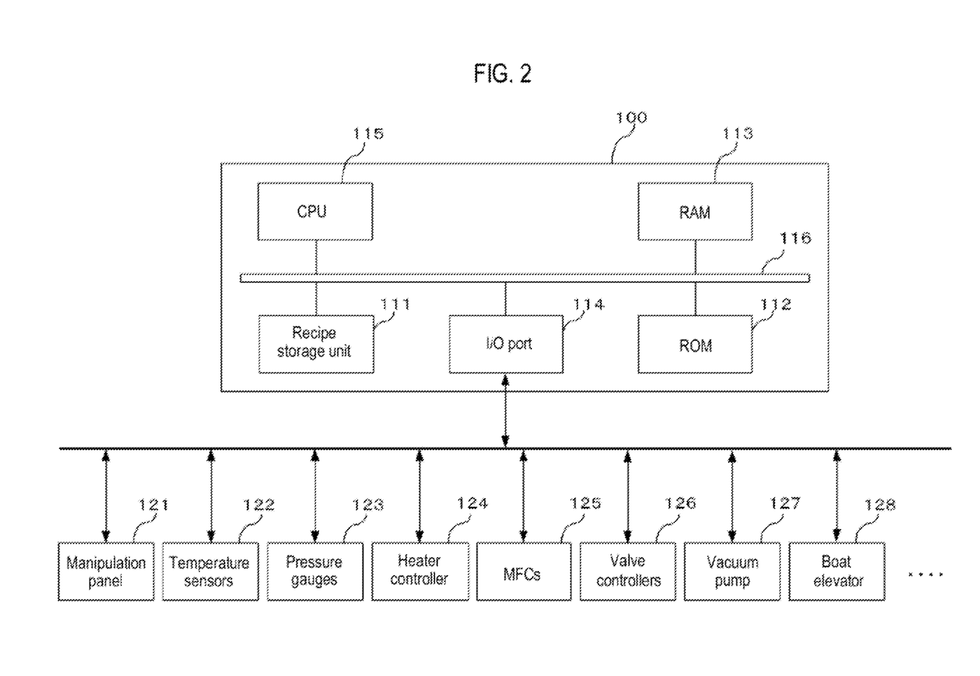

The processing apparatus 1 further includes a control unit 100 configured to control the respective parts of the apparatus. FIG. 2 shows the configuration of the control unit 100. As shown in FIG. 2, a manipulation panel 121, the temperature sensors 122, the pressure gauges 123, a heater controller 124, the MFCs 125, valve controllers 126, the vacuum pump 127, the boat elevator 128 and the like are connected to the control unit 100.

The manipulation panel 121 is provided with a display and manipulation buttons. The manipulation panel 121 transmits operator's instructions to the control unit 100 and displays a variety of information received from the control unit 100 on the display thereof.

The temperature sensors 122 measure the temperatures of the respective parts existing within the reaction tube 2 and within the exhaust pipe, and notify the measured values to the control unit 100. The pressure gauges 123 are configured to measure the pressures of the respective parts within the reaction tube 2 and within the exhaust pipe, and notify the measured values to the control unit 100.

The heater controller 124 is configured to individually control the heaters 7. In response to the instructions received from the control unit 100, the heater controller 124 allows an electric current supply to the heaters 7 to heat the heaters 7. Moreover, the heater controller 124 measures the respective power consumptions of the heaters 7 and notifies the measured power consumptions to the control unit 100.

The respective MFCs 125 are installed in the source gas supply pipe 8, the oxidizing gas supply pipe 9, the nitrogen gas supply pipe 10 and the annealing gas supply pipe 11. The MFCs 125 control the flow rates of the gases flowing through the respective pipes 8 to 11 at the rates instructed by the control unit 100. Also, the MFCs 125 measure the actual flow rates of the gases and notify the measured flow rates to the control unit 100.

The valve controllers 126 are installed in the respective pipes 8 to 11 and control the opening degrees of the valves installed in the respective pipes 8 to 11 at the values instructed by the control unit 100. The vacuum pump 127 is connected to the exhaust pipe and exhausts the gas existing within the reaction tube 2.

The boat elevator 128 moves the lid 5 upward to thereby load the wafer boat 6 (the semiconductor wafers W) into the reaction tube 2. The boat elevator 128 moves the lid 5 downward to thereby unload the wafer boat 6 (the semiconductor wafers W) from the interior of the reaction tube 2.

The control unit 100 includes a recipe storage unit 111, a ROM (Read Only Memory) 112, a RAM (Random Access Memory) 113, an I/O port (Input/Output port) 114, a CPU (Central Processing Unit) 115, and a bus 116 configured to interconnect them.

A setup recipe and a plurality of process recipes are stored in the recipe storage unit 111. At the time of manufacture of the processing apparatus 1, only the setup recipe is stored in the recipe storage unit 111. The setup recipe is executed to generate thermal models and the like in conformity with individual processing apparatuses. A process recipe is prepared for each of heat treatments (processes) actually performed by a user. Each of the process recipes defines the temperature changes of the respective parts, the pressure changes within the reaction tube 2, and the supply start/stop timings and the supply amounts of various types of gases, during the time period from the time when the semiconductor wafers W are loaded into the reaction tube 2 to the time when the processed semiconductor wafers W are unloaded from the reaction tube 2.

The ROM 112 is configured by an EEPROM (Electrically Erasable Programmable Read Only Memory), a flash memory, a hard disk or the like. The ROM 112 is a recording medium that stores an operation program of the CPU 115. The RAM 113 serves as a work area of the CPU 115.

The I/O port 114 is connected to the manipulation panel 121, the temperature sensors 122, the pressure gauges 123, the heater controller 124, the MFCs 125, the valve controllers 126, the vacuum pump 127, the boat elevator 128 and so forth. The I/O port 114 controls the input and output of data and signals.

The CPU 115 constitutes a core of the control unit 100 and executes the operation program stored in the ROM 112. In response to the instructions received via the manipulation panel 121, the CPU 115 controls the operation of the processing apparatus 1 pursuant to the recipes (process recipes) stored in the recipe storage unit 111. That is to say, the CPU 115 causes the temperature sensors 122, the pressure gauges 123 and the MFCs 125 to measure the temperatures, pressures and flow rates of the respective parts within the reaction tube 2 and within the exhaust pipe. Based on the measurement data, the CPU 115 outputs control signals to the heater controller 124, the MFCs 125, the valve controllers 126, the vacuum pump 127 and so forth, thereby controlling the respective parts in accordance with the process recipes. The bus 116 delivers information between the respective parts.

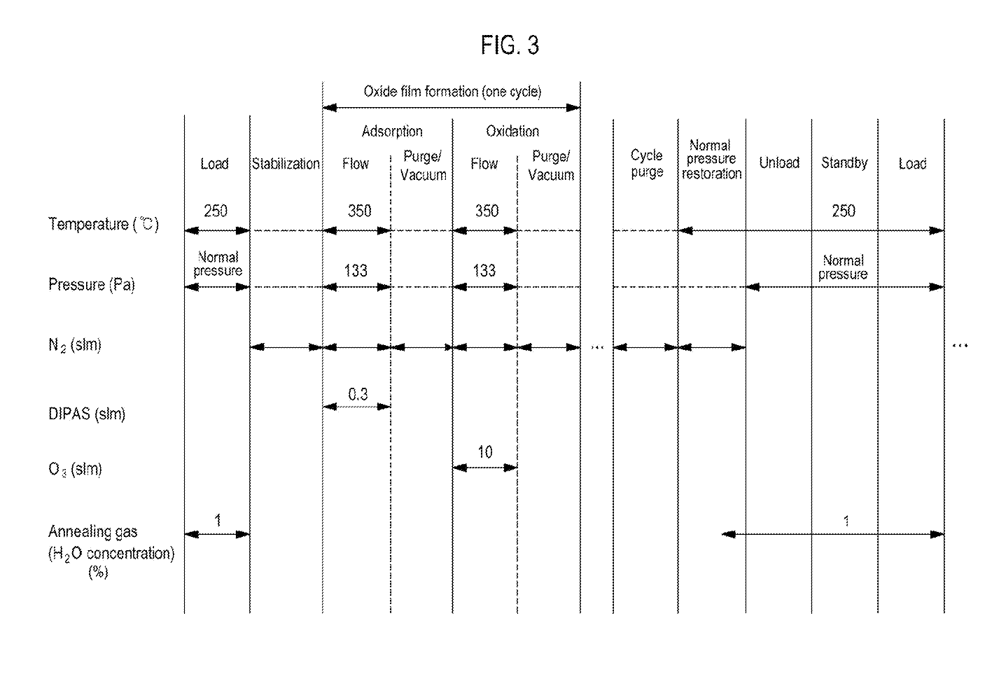

Next, a silicon oxide film forming method using the processing apparatus 1 configured as above will be described with reference to the recipe (time sequence) shown in FIG. 3. In the silicon oxide film forming method of the present embodiment, a silicon oxide film is formed on a semiconductor wafer W by an ALD method or a CVD (Chemical Vapor Deposition) method.

As shown in FIG. 3, the ALD method of the present embodiment includes the adsorption process to have silicon (Si) adsorbed to the surface of the semiconductor wafer W and the oxidation process to oxidize the adsorbed Si. The adsorption process and the oxidation process form one cycle of the ALD method. In the present embodiment, as shown in FIG. 3, diisopropylaminosilane (DIPAS), ozone (O₃), nitrogen (N₂) and water vapor (H₂O) are used as a Si source gas, an oxidizing gas, a diluting gas and an annealing gas, respectively. The cycle shown in FIG. 3 is performed (repeated) a plurality number of times, e.g., one hundred times, whereby a silicon oxide film having a desired thickness is formed on the semiconductor wafer W.

In the following description, the operations of the respective parts forming the processing apparatus 1 are controlled by the control unit 100 (the CPU 115). The control unit 100 (the CPU 115) controls the heater controller 124 (the heaters 7), the MFCs 125 (the source gas supply pipe 8, etc.), the valve controllers 126 and the vacuum pump 127 in the aforementioned manner, so that the temperature, pressure and flow rates of gases in the reaction tube 2 in the respective processes are set into the conditions conforming to the recipe shown in FIG. 3.

First, the interior of the reaction tube 2 is maintained at a predetermined temperature, e.g., 250 degrees C. as shown in FIG. 3, by the heaters 7. Furthermore, as shown in FIG. 3, an annealing gas, e.g., a gas having an H₂O concentration of 1%, is supplied from the annealing gas supply pipe 11 into the reaction tube 2.

In this regard, the concentration of H₂O contained in the annealing gas may be, in some embodiments, 1% or more, in some other embodiments, 3% or more, and in still other embodiments, 5% or more. By the concentration of H₂O contained in the annealing gas being 1%, it means that the ratio of a water vapor (an H₂O gas) to an air (an O₂ gas and a N₂ gas) is equal to 0.2 slm:20.0 slm (equivalent to 4.0 slm of an O₂ gas and 16.0 slm of an N₂ gas). If the concentration of H₂O contained in the annealing gas is set in this range, it is possible to reduce the film stresses of the silicon oxide film adhering to the internal parts, e.g., the reaction tube 2, of the processing apparatus 1. This is because the H₂O contained in the annealing gas is absorbed to the silicon oxide film adhering to the internal parts of the processing apparatus 1, which may prevent peeling of the silicon oxide film. In this case, the silicon oxide film adhering to the internal parts of the processing apparatus 1 may be harder to be peeled off from the internal parts of the processing apparatus 1. It is therefore possible to prevent the generation of particles.

The internal temperature of the reaction tube 2 may be, in some embodiments, from 100 degrees C. to 600 degrees C., in some other embodiments, from 150 degrees C. to 400 degrees C., and in still other embodiments, from 200 degrees C. to 300 degrees C. If the internal temperature of the reaction tube 2 is set in this range, the H₂O contained in the annealing gas is easily absorbed to the silicon oxide film adhering to the internal parts of the processing apparatus 1, which prevents peeling of the silicon oxide film. Accordingly, the silicon oxide film adhering to the internal parts of the processing apparatus 1 becomes harder to be peeled off from the internal parts of the processing apparatus 1. It is therefore possible to prevent the generation of particles.

Then, the wafer boat 6 accommodating the semiconductor wafers W is mounted on the lid 5. The lid 5 is moved up by the boat elevator 128, thereby loading the semiconductor wafers W (the wafer boat 6) into the reaction tube 2 (load process).

Subsequently, the interior of the reaction tube 2 is set at a predetermined temperature, e.g., 350 degrees C. as shown in FIG. 3, using the heaters 7. Further, a specified amount of nitrogen is supplied from the nitrogen gas supply pipe 10 into the reaction tube 2 while discharging the gas existing within the reaction tube 2. Thus, the internal pressure of the reaction tube 2 is set at a predetermined pressure, e.g., 133 Pa (1 Torr) as shown in FIG. 3 (stabilization process).

Subsequently, an oxide film formation process for forming a silicon oxide film on the semiconductor wafer W is performed. First, the adsorption process for having Si adsorbed to the surface of the semiconductor wafer W is performed. The adsorption process is for supplying a source gas to the semiconductor wafer W and having Si to be adsorbed to the surface of the semiconductor wafer W.

In the adsorption process, a specified amount, e.g., 0.3 slm as shown in FIG. 3, of DIPAS as a Si source is supplied from the source gas supply pipe 8 into the reaction tube 2 and a predetermined amount of nitrogen is supplied from the nitrogen gas supply pipe 10 into the reaction tube 2 (flow process).

In this regard, the internal temperature of the reaction tube 2 may be from the room temperature (RT) to 700 degrees C. in some embodiments. If the internal temperature of the reaction tube 2 is lower than the room temperature, it is likely that a silicon oxide film is not formed. If the internal temperature of the reaction tube 2 is higher than 700 degrees C., it is likely that the film quality and the uniformity in film thickness of the silicon oxide film as formed get deteriorated. The internal temperature of the reaction tube 2 may be, in some embodiments, from the room temperature to 700 degrees C., and in some other embodiments, from the room temperature to 500 degrees C. If the internal temperature of the reaction tube 2 is set in this range, the film quality and the uniformity in film thickness of the silicon oxide film as formed can be further improved.

The supply amount of DIPAS may be, in some embodiments, from 10 sccm to 10 slm. If the supply amount of DIPAS is smaller than 10 sccm, it is likely that Si is not sufficiently supplied to the surface of the semiconductor wafer W. If the supply amount of DIPAS is larger than 10 slm, it is likely that a large amount of Si does not make contribution to a reaction of Si with the surface of the semiconductor wafer W. In some other embodiments, the supply amount of DIPAS may be from 0.1 slm to 3 slm. If the supply amount of DIPAS is set in this range, the reaction of Si with the surface of the semiconductor wafer W can be accelerated.

The internal pressure of the reaction tube 2 may be from 0.133 Pa (0.001 Torr) to 13.3 kPa (100 Torr) in some embodiments. If the internal pressure of the reaction tube 2 is set in this range, the reaction of Si with the surface of the semiconductor wafer W can be accelerated. In some other embodiments, the internal pressure of the reaction tube 2 may be from 40 Pa (0.3 Torr) to 400 Pa (3 Torr). If the internal pressure of the reaction tube 2 is set in this range, it becomes easy to control the internal pressure of the reaction tube 2.

DIPAS supplied into the reaction tube 2 is heated and activated within the reaction tube 2. For that reason, upon supplying DIPAS into the reaction tube 2, the activated Si reacts with the surface of the semiconductor wafer W and is adsorbed to the surface of the semiconductor wafer W.

If a predetermined amount of Si is adsorbed to the surface of the semiconductor wafer W, the supply of DIPAS from the source gas supply pipe 8 and the supply of nitrogen from the nitrogen gas supply pipe 10 are stopped. Then, the gas existing within the reaction tube 2 is discharged to the outside of the reaction tube 2, while a specified amount of nitrogen is supplied from the nitrogen gas supply pipe 10 into the reaction tube 2, for example, as shown in FIG. 3, (purge/vacuum process).

Subsequently, the interior of the reaction tube 2 is set at a predetermined temperature, e.g., 350 degrees C. as shown in FIG. 3, using the heaters 7. Also, as shown in FIG. 3, a specified amount of nitrogen is supplied from the nitrogen gas supply pipe 10 into the reaction tube 2, while discharging the gas existing within the reaction tube 2. Thus, the internal pressure of the reaction tube 2 is set at a predetermined pressure, e.g., 133 Pa (1 Torr) as shown in FIG. 3.

Then, the oxidation process to oxidize the surface of the semiconductor wafer W is performed. In the oxidation process, an oxidizing gas is supplied onto the Si-adsorbed semiconductor wafer W to oxidize the adsorbed Si. In the present embodiment, the adsorbed Si is oxidized by supplying ozone (O₃) onto the semiconductor wafer W.

In the oxidation process, a specified amount, e.g., 10 slm as shown in FIG. 3, of ozone is supplied from the oxidizing gas supply pipe 9 into the reaction tube 2. Moreover, as shown in FIG. 3, a specified amount of nitrogen as a diluting gas is supplied from the nitrogen gas supply pipe 10 into the reaction tube 2 (flow process).

In this regard, the supply amount of ozone may be, in some embodiments, from 1 sccm to 50 slm, in some other embodiments, from 0.1 slm to 20 slm, and in still other embodiments, from 1 slm to 10 slm. If the supply amount of ozone is set in this range, it is possible to oxidize the Si adsorbed to the surface of the wafer W to such a level enough to form a silicon oxide film.

The internal pressure of the reaction tube 2 may be from 0.133 Pa (0.001 Torr) to 13.3 kPa (100 Torr) in some embodiments. If the internal pressure of the reaction tube 2 is set in this range, the oxidization of Si existing on the surface of the semiconductor wafer W can be accelerated. In some other embodiments, the internal pressure of the reaction tube 2 may be from 40 Pa (0.3 Torr) to 400 Pa (3 Torr). If the internal pressure of the reaction tube 2 is set in this range, it becomes easy to control the internal pressure of the reaction tube 2.

If ozone is supplied into the reaction tube 2, the Si adsorbed to the surface of the semiconductor wafer W is oxidized form a silicon oxide film on the semiconductor wafer W. If a silicon oxide film having a desired thickness is formed on the semiconductor wafer W, the supply of ozone from the oxidizing gas supply pipe 9 is stopped. Also, the supply of nitrogen from the nitrogen gas supply pipe 10 is stopped. Then, the gas existing within the reaction tube 2 is discharged to the outside of the reaction tube 2, while a specified amount of nitrogen is supplied from the nitrogen gas supply pipe 10 into the reaction tube 2, as shown in FIG. 3 (purge/vacuum process).

By performing the purge/vacuum process in the oxidation process, one cycle of the ALD method including the adsorption process and the oxidation process is finished. Subsequently, another cycle of the ALD method may be started from the adsorption process, and such a cycle may be repeated a predetermined number of times. In this manner, a silicon oxide film having a desired thickness is formed on the semiconductor wafer W.

When the silicon oxide film having a desired thickness is formed on the semiconductor wafer W, an operation of supplying a specified amount of nitrogen from the nitrogen gas supply pipe 10 into the reaction tube 2 and discharging the gas existing within the reaction tube 2 to the outside of the reaction tube 2 is repeated a plurality number of times (cycle purge process). Then, the interior of the reaction tube 2 is maintained at a predetermined loading temperature, e.g., 250 degrees C. as shown in FIG. 3, using the heaters 7. In this state, the interior of the furnace is cycle-purged with N₂ and is returned to the normal pressure (normal pressure restoration process).

At the stage where the interior of the furnace is almost close to the normal pressure, an annealing gas, e.g., a gas having the H₂O concentration of 1%, is supplied from the annealing gas supply pipe 11 into the furnace (the reaction tube 2) as shown in FIG. 3. In some embodiments, the ranges of the H₂O concentration in the annealing gas and the internal temperature of the reaction tube 2 may be the same as those used in the load process.

Then, the lid 5 is moved down by the boat elevator 128, thereby unloading the semiconductor wafers W (unload process). The unload process refers to a process in which the wafer boat 6 is moved from a regular position within the furnace to a regular position outside the furnace. Thereafter, preparation is performed by, e.g., mounting the wafer boat 6 accommodating semiconductor wafers W to be newly processed on the lid 5 (standby process). The standby process refers to a wafer discharging process in which the processed semiconductor wafers W are recovered from the wafer boat 6 and a wafer charging process in which the semiconductor wafers W to be newly processed are mounted into the wafer boat 6. Then, the lid 5 is moved up by the boat elevator 128, thereby loading the semiconductor wafers W (the wafer boat 6) into the reaction tube 2 (load process). In the aforementioned manner, a silicon oxide film having a desired thickness is subsequently formed on new semiconductor wafers W.

As described above, the gas having the H₂O concentration of 1% (the annealing gas) is supplied from the annealing gas supply pipe 11 into the reaction tube 2 during a time period between the unload process and the load process where particles are easily generated. Thus, the H₂O contained in the gas is easily absorbed to the silicon oxide film adhering to the internal parts of the processing apparatus 1, which prevents peeling of the silicon oxide film. For that reason, the silicon oxide film adhering to the internal parts of the processing apparatus 1 is harder to be peeled off from the internal parts of the processing apparatus 1. It is therefore possible to prevent the generation of particles.

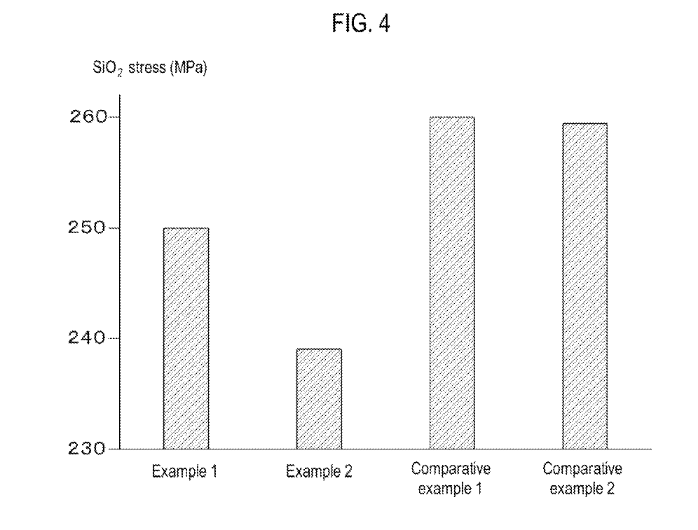

In order to confirm the effects of the present disclosure, a silicon oxide film of 50 nm in thickness was formed on the semiconductor wafer W by the same method as the aforementioned silicon oxide film forming method except that the internal temperature of the reaction tube 2 is set at 150 degrees C. in the adsorption process and the oxidation process. The film stresses of the silicon oxide film thus formed were measured (example 1). Furthermore, a silicon oxide film of 50 nm in thickness was formed on the semiconductor wafer W by the same method as the aforementioned silicon oxide film forming method except that the H₂O concentration of the annealing gas is set at 5%. The film stresses of the silicon oxide film thus formed were measured (example 2). For the sake of comparison, silicon oxide films of 50 nm in thickness were formed on the semiconductor wafer W by the same method as the aforementioned silicon oxide film forming method, using a gas mixture containing 20% of oxygen and 80% of nitrogen as the annealing gas (comparative example 1) and using a 100% nitrogen gas as the annealing gas (comparative example 2). The film stresses of the silicon oxide films thus formed were measured. The results are shown in FIG. 4.

As shown in FIG. 4, it was confirmed that the film stresses of the silicon oxide film decrease if a gas having the H₂O concentration of 1% or more is used as the annealing gas. Particularly, it was confirmed that the film stresses of the silicon oxide film significantly decrease if a gas having the H₂O concentration of 5% is used as the annealing gas.

As described above, according to the present embodiment, a gas containing water vapor (H₂O) is used as the annealing gas. Thus, the H₂O contained in the gas is easily absorbed to the silicon oxide film adhering to the internal parts of the processing apparatus 1, which prevents peeling of the silicon oxide film. For that reason, the silicon oxide film adhering to the internal parts of the processing apparatus 1 is harder to be peeled off from the internal parts of the processing apparatus 1. It is therefore possible to prevent the generation of particles.

The present disclosure is not limited to the aforementioned embodiment but may be modified and applied in many different forms. Hereinafter, other embodiments applicable to the present disclosure will be described.

In the aforementioned embodiment, the present disclosure has been described by taking as an example where DIPAS is used as the Si source. However, it is only necessary that the Si source be an organic source gas capable of forming a silicon oxide film. For example, SiH₄, SiH₃Cl, SiH₂Cl₂, SiHCl₃, SiH₃(NHC(CH₃)₃), SiH₃(N(CH₃)₂), SiH₂(NHC(CH₃)₃)₂ and SiH(N(CH₃)₂)₃ may be used as the Si source.

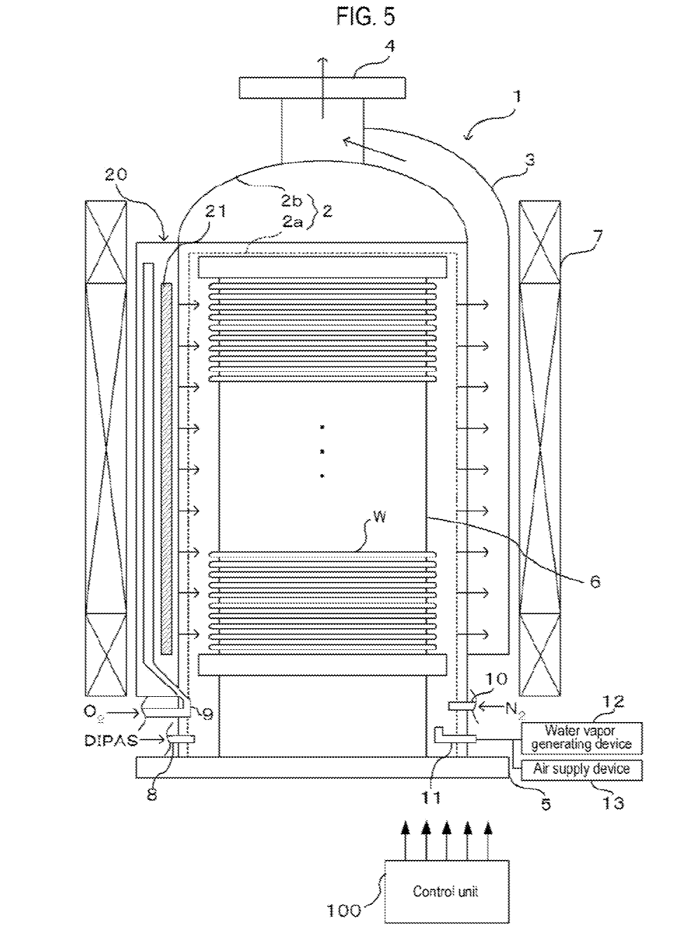

In the aforementioned embodiment, the present disclosure has been described by taking as an example where ozone is used as the oxidizing gas. However, it is only necessary that the oxidizing gas be a gas capable of oxidizing the adsorbed Si to form a silicon oxide film. For example, oxygen radicals generated by treating oxygen (O₂) with plasma, catalysts, ultraviolet rays, heat, magnetic forces or the like may be used as the oxidizing gas. In case where the oxidizing gas is activated by, e.g., plasma, it may be possible to use a processing apparatus 1 shown in FIG. 5.

In the processing apparatus 1 shown in FIG. 5, a plasma generating unit 20 is installed at the opposite side of the reaction tube 2 from the side where the exhaust part 3 is disposed. The plasma generating unit 20 is provided with an electrode 21. The oxidizing gas supply pipe 9 is inserted through the electrode 21. The electrode 21 is connected to a high-frequency power supply, a matching unit and so forth, which are not shown. High-frequency electric power is applied from the high-frequency power supply to the electrode 21 through the matching unit, thereby plasma-exciting (activating) the oxidizing gas (O₂) supplied to the electrode 21 and consequently generating oxygen radicals (O₂*). The oxygen radicals (O₂*) thus generated is supplied from the plasma generating unit 20 into the reaction tube 2.

In the aforementioned embodiment, the present disclosure has been described by taking as an example where the annealing gas is supplied into the reaction tube 2 during the time period between the unload process and the load process. Alternatively, the annealing gas may be supplied into the reaction tube 2 during at least one of the unload process, the standby process and the load process. Even in this case, the H₂O contained in the gas is easily absorbed to the silicon oxide film adhering to the internal parts of the processing apparatus 1, which prevents peeling of the silicon oxide film. For that reason, the silicon oxide film adhering to the internal parts of the processing apparatus 1 is harder to be peeled off from the internal parts of the processing apparatus 1. It is therefore possible to prevent the generation of particles.

In some embodiments, the supply of the annealing gas may be performed only during the standby process. Seeing that a specified period of time is needed in the standby process to recover the semiconductor wafers W from the wafer boat 6 and to mount new semiconductor wafers W into the wafer boat 6, no additional time (down time) is required for supplying the annealing gas.

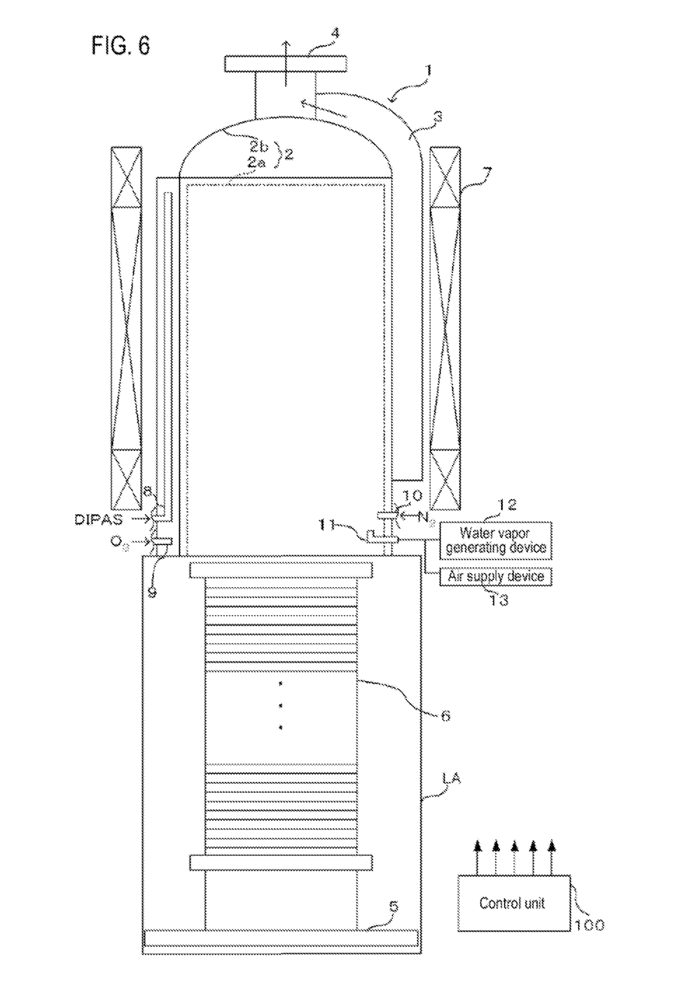

FIG. 6 shows the outline of the processing apparatus 1 in the standby process. As shown in FIG. 6, in the standby process, the lid 5 is moved down by the boat elevator 128. The wafer boat 6 accommodating the semiconductor wafers W is arranged within a loading area LA that exists below the reaction tube 2 (outside the furnace). In this state, the annealing gas is supplied from the annealing gas supply pipe 11 into the reaction tube 2. The ambient air existing within a clean room may be directly used as the annealing gas insofar as the H₂O concentration therein is equal to or larger than a desired concentration. Thus, the H₂O contained in the annealing gas is easily absorbed to the silicon oxide film adhering to the internal parts of the processing apparatus 1, which prevents peeling of the silicon oxide film. For that reason, the silicon oxide film adhering to the internal parts of the processing apparatus 1 is harder to be peeled off from the internal parts of the processing apparatus 1. It is therefore possible to prevent the generation of particles.

In some embodiments, after supplying the annealing gas into the reaction tube 2 such that the internal pressure of the reaction tube 2 becomes a predetermined pressure, e.g., 86.45 kPa (650 Torr), a specified amount of nitrogen may be supplied from the nitrogen gas supply pipe 10 into the reaction tube 2 to thereby substitute the internal atmosphere of the reaction tube 2 with nitrogen. Through the nitrogen substitution, the moisture contained in the annealing gas (the ambient air component) can be supplied to the interior of the reaction tube 2 only. Also, the annealing gas can be supplied into the reaction tube 2 while keeping low the oxygen concentration within the loading area LA. As a result, it is possible to prevent the generation of particles, especially fine particles.

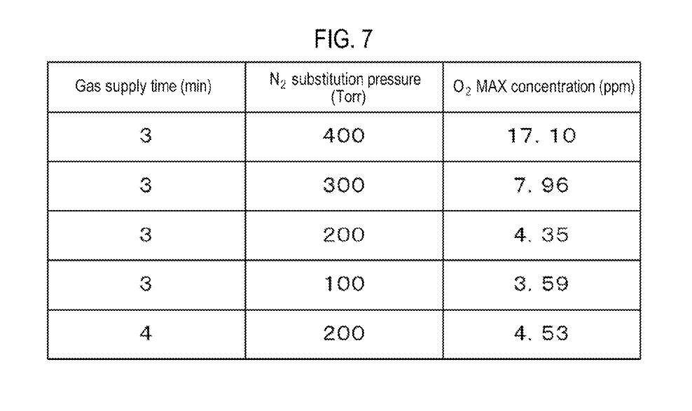

FIG. 7 shows the relationship between the annealing gas supply time, the nitrogen substitution pressure (N₂ substitution pressure) and the maximum oxygen concentration (O₂ MAX concentration) within the loading area LA. As shown in FIG. 7, if the N₂ substitution pressure available after the supply of the annealing gas is set equal to or lower than 200 Torr (26.6 kPa), the O₂ MAX concentration can be reduced. For that reason, in some embodiments, the nitrogen substitution pressure available after the supply of the annealing gas may be set to a vacuum level of 26.6 kPa (200 Torr), so that the normal pressure is directly restored by the nitrogen substitution.

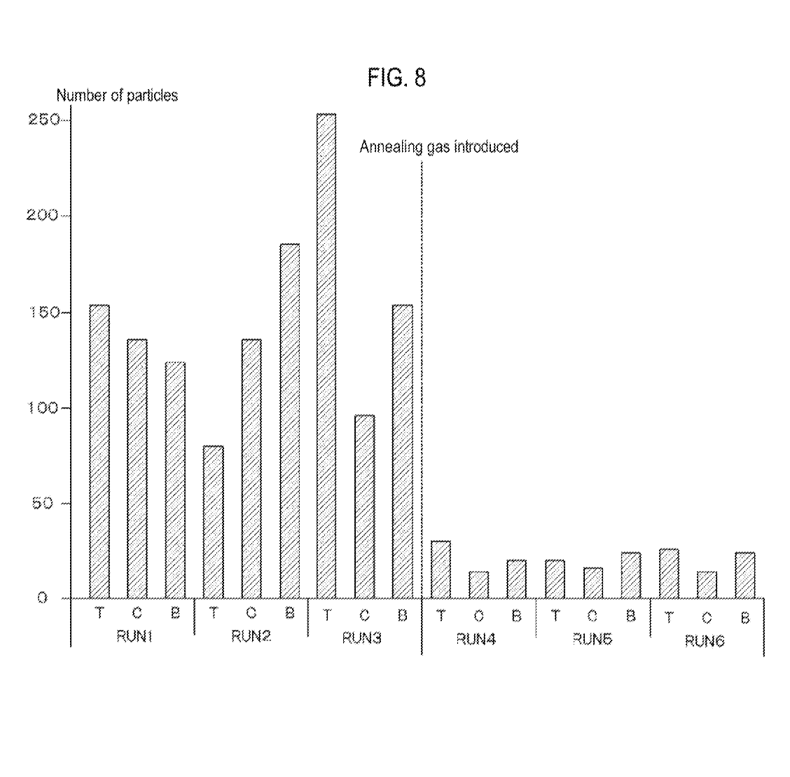

In order to confirm the effects attributable to the annealing gas supply during the standby process, a silicon oxide film of 12.2 μm in thickness was formed on the semiconductor wafers W by the aforementioned silicon oxide film forming method in every three runs RUN1, RUN2 and RUN3, and the numbers of particles of 0.05 μm or more in size generated on the silicon oxide films formed in the top portion T, the center portion C and the bottom portion B of the reaction tube 2, respectively, were measured in each of the three runs RUN1, RUN2 and RUN3. Then, after the annealing gas was supplied during the standby process, a silicon oxide film of 12.2 μm in thickness was formed again on the semiconductor wafers W by the aforementioned silicon oxide film forming method in every three runs RUN4, RUN5 and RUN6, and the numbers of particles of 0.05 μm or more in size generated on the silicon oxide films formed in the top portion T, the center portion C and the bottom portion B of the reaction tube 2, respectively, were measured in each of the three runs RUN4, RUN5 and RUN6. The numbers of particles in the respective portions thus measured are shown in FIG. 8.

As shown in FIG. 8, it was confirmed that the numbers of particles in the respective portions as measured are significantly reduced by supplying the annealing gas during the standby process. Thus, it was confirmed that the generation of particles can be prevented by supplying the annealing gas during the standby process.

In the aforementioned embodiment, the present disclosure has been described by taking as an example where the annealing gas is supplied into the reaction tube 2 at the stage where the internal pressure is close to the normal pressure in the normal pressure restoration process. As an alternative example, the annealing gas may be supplied into the reaction tube 2 simultaneously with the start of the unload process. Even in this case, it is possible to prevent the generation of particles.

In the aforementioned embodiment, the present disclosure has been described by taking as an example where the gas containing water vapor is supplied into the reaction tube 2 using the water vapor generating device 12 and the air supply device 13. As an alternative example, if the loading area LA of the processing apparatus 1 is provided with an N₂ load-lock mechanism, devices for supplying a nitrogen gas and an oxygen gas may be installed without installing the air supply device 13. In this case, a gas having an H₂O concentration of 1% is supplied into the reaction tube 2 by controlling the flow rate ratio of an H₂O gas, an O₂ gas and an N₂ gas to become 0.2 slm:4.0 slm:16.0 slm.

Moreover, a gas containing water vapor may be supplied into the reaction tube 2 by maintaining the loading area LA of the processing apparatus 1 in the same atmospheric atmosphere as the clean room and by supplying the ambient air existing within the loading area LA into the reaction tube 2 during the load and unload processes.

In the aforementioned embodiment, the present disclosure has been described by taking as an example where the silicon oxide film is formed on the semiconductor wafer W by performing one hundred cycles of the oxide film formation process. As an alternative example, the number of cycles may be reduced to, e.g., fifty cycles. Moreover, the number of cycles may be increased to, e.g., two hundred cycles. Even in these cases, a silicon oxide film having a desired thickness can be formed by adjusting, e.g., the supply amounts of the Si source and the oxygen depending on the number of cycles.

In the aforementioned embodiment, the present disclosure has been described by taking as an example where the silicon oxide film is formed on the semiconductor wafer W using the ALD method. However, the present disclosure is not limited to the use of the ALD method. Alternatively, a silicon oxide film may be formed on the semiconductor wafer W using a CVD method.

In the aforementioned embodiment, the present disclosure has been described by taking as an example where the nitrogen as the diluting gas is supplied during the supply of the source gas and the oxidizing gas. Alternatively, the nitrogen may not be supplied during the supply of the source gas and the oxidizing gas. However, since it becomes easy to set the processing time and the like when the nitrogen is supplied as the diluting gas, it is preferable to supply the diluting gas. The diluting gas may be an inert gas other than the nitrogen, e.g., helium (He), neon (Ne), argon (Ar), krypton (Kr) or xenon (Xe).

In the aforementioned embodiment, the present disclosure has been described by taking as an example where the batch-type processing apparatus having a double tube structure is used as the processing apparatus 1. As an alternative example, the present disclosure may be applied to a batch-type processing apparatus having a single tube structure. Moreover, the present disclosure may be applied to a batch-type horizontal processing apparatus or a single-substrate-type processing apparatus. In addition, the workpiece is not limited to the semiconductor wafer W but may be, e.g., a glass substrate for an LCD (Liquid Crystal Display).

The control unit 100 employed in the embodiments of the present disclosure can be realized by using a typical computer system instead of a dedicated computer system. For example, the control unit 100 for performing the aforementioned processes can be configured by installing programs for executing the processes into a general-purpose computer through the use of a recording medium (a flexible disc, a CD-ROM (Compact Disc-Read Only Memory) or the like) which stores programs for performing the aforementioned processes.

The programs can be provided by an arbitrary means. The programs may be provided not only by the recording medium mentioned above but also through a communication line, a communication network, a communication system or the like. In the latter case, the programs may be posted on bulletin boards (BBS: Bulletin Board System) and provided through a network together with carrier waves. The program thus provided is started up and executed in the same manner as other application programs under the control of an operating system, thereby performing the processes described above.

The present disclosure is useful in a silicon oxide film forming method and a silicon oxide film forming apparatus.

According to the present disclosure, it is possible to prevent the generation of particles.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A silicon oxide film forming method comprising performing a set one or more times, the set including:
a standby process in which a workpiece is accommodated into and recovered from a boat;
a load process in which the workpiece accommodated in the boat is loaded into a reaction chamber;
a silicon oxide film formation process in which a silicon oxide film is formed on the workpiece accommodated within the reaction chamber; and
an unload process in which the workpiece having the silicon oxide film is unloaded from the reaction chamber,
wherein, in at least one of the unload process, the standby process and the load process, a gas containing water vapor is supplied into the reaction chamber while an interior of the reaction chamber is heated.

2. The method of claim 1, wherein a concentration of the water vapor in the gas is 1% or more.

3. The method of claim 1, wherein, during the unload process, the standby process and the load process, the gas containing the water vapor is supplied into the reaction chamber while the interior of the reaction chamber is heated.

4. The method of claim 1, wherein, in the silicon oxide film formation process, the silicon oxide film is formed on the workpiece while the interior of the reaction chamber is depressurized below the normal pressure,
wherein the set further includes a normal pressure restoration process in which the internal pressure of the reaction chamber is returned to the normal pressure, the normal pressure restoration process being performed between the silicon oxide film formation process and the unload process, and
wherein the gas containing the water vapor is supplied into the reaction chamber, simultaneously when the internal pressure of the reaction chamber returns to the normal pressure during the normal pressure restoration process, or simultaneously with the start of the unload process.

5. The method of claim 1, wherein, in the standby process only, the gas containing the water vapor is supplied into the reaction chamber while the interior of the reaction chamber is heated.

6. The method of claim 5, wherein, in the standby process, the gas containing the water vapor is supplied into the reaction chamber such that the internal pressure of the reaction chamber becomes a predetermined pressure and, then, a nitrogen substitution is performed by supplying nitrogen into the reaction chamber such that the internal pressure of the reaction chamber becomes equal to or lower than 26.6 kPa.

7. The method of claim 1, wherein the gas containing the water vapor supplied into the reaction chamber is a gas mixture of water vapor, a nitrogen gas and an oxygen gas, or an air.

8. The method of claim 1, wherein the silicon oxide film formation process comprises performing a set one or more times, the set including:
an adsorption process for supplying a silicon source gas into the reaction chamber accommodating the workpiece to have silicon adsorbed to the workpiece; and
an oxidation process for supplying an oxidizing gas to the silicon adsorbed in the adsorption process and oxidizing the silicon into the silicon oxide film on the workpiece.

9. The method of claim 8, wherein, in the oxidation process, ozone is supplied into the reaction chamber set at 200 degrees C. to 600 degrees C. and is activated, the activated ozone being supplied to the adsorbed silicon to oxidize the silicon into the silicon oxide film on the workpiece.

10. A silicon oxide film forming apparatus, comprising:
a reaction chamber configured to accommodate a workpiece mounted on a boat;
a heating unit configured to heat an interior of the reaction chamber to a predetermined temperature;
a film forming gas supply unit configured to supply a film forming gas into the reaction chamber;
a water-vapor-containing gas supply unit configured to supply a water-vapor-containing gas into the reaction chamber; and
a control unit configured to control the heating unit, the film forming gas supply unit and the water-vapor-containing gas supply unit,
wherein the control unit is configured to perform one or more times a set including: a standby process in which the workpiece is accommodated into and recovered from the boat; a load process in which the workpiece accommodate in the boat is loaded into the reaction chamber; a silicon oxide film formation process in which the film forming gas supply unit is controlled to form a silicon oxide film on the workpiece accommodated within the reaction chamber; and an unload process in which the workpiece having the silicon oxide film formed thereon is unloaded from the reaction chamber, and
wherein, in at least one of the load process, the standby process and the unload process, the water-vapor-containing gas supply unit is controlled to supply the water-vapor-containing gas into the reaction chamber while the heating unit is controlled to heat the interior of the reaction chamber.
